(19) United States
(12) Patent Application Publication
(10) Pub. No.: US 2026/0149412 A1
(43) Pub. Date: May 28, 2026

(54) RADIO FREQUENCY POWER AMPLIFIER BASED ON TRANSFORMER MATCHING

(71) Applicant: BEIJING ONMICRO ELECTRONICS CO., LTD., Beijing (CN)

(72) Inventors: Xiaodong XU, Beijing (CN); Zihan ZHAO, Beijing (CN); Yongxue QIAN, Beijing (CN); Xin HUANG, Beijing (CN); Hao MENG, Beijing (CN)

(73) Assignee: BEIJING ONMICRO ELECTRONICS CO., LTD., Beijing (CN)

(21) Appl. No.: 19/397,264

(22) Filed: Nov. 21, 2025

(30) Foreign Application Priority Data
Nov. 22, 2024 (CN) 202411686756.6

(51) Int. Cl. H03F 1/02; H03F 1/56; H03F 3/26

(52) U.S. Cl. CPC H03F 1/0288; H03F 1/56; H03F 3/265; H03F 2200/387; H03F 2200/451

(57) ABSTRACT

A radio frequency (RF) power amplifier based on transformer matching is provided. The RF power amplifier includes: a first-stage amplification circuit configured with an input terminal and an output terminal, wherein the output terminal of the first-stage amplification circuit is configured to be connected to one terminal of a main coil of a first transformer; the first transformer configured to include the main coil and a secondary coil, wherein one terminal of the secondary coil is grounded and the other terminal of the secondary coil is connected to a medium-low power mode input terminal of a power switch; the second-stage amplification circuit configured with an input terminal for receiving the amplified RF signal from the first-stage amplification circuit, wherein an output terminal of the second-stage amplification circuit is configured to be connected to a high power mode input terminal of the power switch.

### BACKGROUND

### 1. Field

The disclosure relates to the field of wireless communication, in particular to a radio frequency (RF) power amplifier which uses transformer matching to realize a high-efficiency medium-power mode.

### 2. Description of the Related Art

The service life of battery is a very important index in the design of mobile communication terminal. One of the most important parameters affecting battery service life is the average power amplifier utilization efficiency (APUE). The APUE can be calculated based on the statistical power probability density function (PDF), and can be calculated by the following Formula 1.

$${Eff}_{APUE} = \frac{{\sum }_{i = 1}^{i = N} PDF ( Pout , i ) * Pout ( i )}{{\sum }_{i = 1}^{i = N} PDF ( Pout , i ) * Vcc ( i ) * Icc ( i )} \qquad Formula 1$$

Wherein EffAPUE is the average power amplifier use efficiency of the amplifier; PDF(Pout,i) is the statistical power probability density function with inputs Pout and i, wherein i is the number of integration points, and Pout is the output power of the amplifier; Pout(i) is the output power of the amplifier with input i; VCC (i) represents the power amplifier supply voltage corresponding to Pout (i); and Icc (i) represents the power amplifier DC current corresponding to Pout (i).

For the earlier 3rd generation WCDMA wireless communication system, the statistical power probability density function, often referred to as DG09 profile, is widely used in talk time and battery life calculation. FIG. 1 shows the DG09 profile of the power probability density function of the mobile phone power amplifier of the third generation WCDMA wireless communication system. Referring to DG09 profile, the maximum probability peaks around 0 dBm, therefore reducing power consumption at 0 dBm can improve battery life. FIG. 2 shows the DG09 profile of the power probability density function of the mobile phone power amplifier in 4G LTE and 5G NR wireless communication systems. Referring to FIG. 2, the peak value of the power probability density function is increased to about 14 dBm, therefore optimizing the output power around 14 dBm can significantly improve the battery life and talk time. In the present disclosure, the working mode with an output power of less than 14 dBm is defined as a medium-low power mode. Furthermore, in the present disclosure, the medium power mode can be defined as the working mode in which the rated output power of the power amplifier is 14 dBm and the low power mode is defined as the working mode when the rated output power of the power amplifier is 4 dBm. On the other hand, the high power mode generally refers to the state when the output power of the power amplifier is larger than the medium power mode. According to the embodiment of the present disclosure, the high power mode can be defined as the operation mode in which the rated output power of the power amplifier is up to 29.5 dBm.

In order to improve battery life and talk time, the RF power amplifier can be configured to work in high power mode and medium power mode (or medium-low power mode). When the RF power amplifier is configured in high power mode and medium power mode, in order to prevent the medium power mode from affecting the high power mode, a medium power mode matching network is generally not provided, and a 50 ohm load is directly connected through a switch. FIG. 3 is a schematic diagram showing a two stages power amplifier in which a first-stage amplifier circuit is directly connected to an output of the amplifier in the medium power mode. As shown in FIG. 3, when the RF power amplifier works in the medium power mode, the RF signal is directly connected to the medium-low power mode input terminal of the power switch from the choke (choke inductor) of the driving stage of the power amplifier, without a matching network or a decoupling element matching mode. However, the optimum load impedance of the driving stage of the power amplifier (the first stage) is often not around 50 ohms, which leads to the non-optimal efficiency of the power amplifier in the medium power mode. At the same time, compared with the parasitic reactance of the output stage circuit of the RF power amplifier, the direct connection of 50 ohm load often leads to the increase of the Q value of the circuit, which leads to the decrease of the power working bandwidth of the RF power amplifier.

### SUMMARY

In accordance with an aspect of the disclosure, a RF power amplifier based on transformer matching is provided. The RF power amplifier includes: a first-stage amplification circuit configured with an input terminal for receiving RF input signals and an output terminal connected to the input terminal of a second-stage amplification circuit, and the output terminal of the first-stage amplification circuit is also configured to be connected to one terminal of a main coil of a first transformer, to be connected to a power supply voltage through the main coil of the first transformer; the first transformer configured to include the main coil and a secondary coil, wherein the main coil is configured between the power supply voltage and the output terminal of the first-stage amplification circuit, and one terminal of the secondary coil is grounded and the other terminal of the secondary coil is connected to a medium-low power mode input terminal of a power switch through a first capacitor; the second-stage amplification circuit configured with the input terminal for receiving the amplified RF signal from the first-stage amplification circuit, and its output terminal configured to be connected to the high power mode input terminal of the power switch; and the power switch configured as a single-pole double-throw switch or a single-pole multi-throw switch, wherein the power switch is configured to be connected with the medium-low power mode input terminal when the RF power amplifier works in the medium-low power mode, and to be connected with the high power mode input terminal when the RF power amplifier works in the high power mode.

In accordance with another aspect of the disclosure, a RF power amplifier based on transformer matching is provided, wherein the first-stage amplification circuit and the second-stage amplification circuit are configured as single-ended power amplifiers, wherein the output terminal of the first-stage amplification circuit is connected to the input terminal of the second-stage amplification circuit through an inter-stage matching network, and the output terminal of the second-stage amplification circuit is connected to the high power mode input terminal of the power switch through an output matching network.

In accordance with another aspect of the disclosure, a RF power amplifier based on transformer matching is provided, wherein the output terminal of the second-stage amplification circuit is also configured to be connected to the power supply voltage through the output stage choke.

In accordance with another aspect of the disclosure, a RF power amplifier based on transformer matching is provided, wherein the second-stage amplification circuit is configured as a push-pull power amplifier, which includes an input coupling transformer, a first amplification branch, a second amplification branch and an output coupling transformer, wherein the output terminal of the first-stage amplification circuit is connected to one terminal of the main coil of the input coupling transformer, and the other terminal of the main coil of the input coupling transformer is grounded, wherein the input terminal of the first amplification branch and the input terminal of the second amplification branch are respectively connected to one of two terminals of the secondary coil of the input coupling transformer, and the output terminal of the first amplification branch and the output terminal of the second amplification branch are respectively connected to one of two terminals of the main coil of the output coupling transformer, wherein one terminal of the secondary coil of the output coupling transformer is configured to be grounded, and the other terminal is connected to the high power mode input terminal of the power switch.

In accordance with another aspect of the disclosure, a RF power amplifier based on transformer matching is provided, wherein the secondary coil of the input coupling transformer is configured to be grounded at the middle portion, and the main coil of the output coupling transformer is configured to be grounded at the middle portion.

In accordance with another aspect of the disclosure, a RF power amplifier based on transformer matching is provided, wherein the RF power amplifier is configured as a Doherty power amplifier, the first-stage amplification circuit is configured as the first-stage amplification circuit of a carrier amplifier in the Doherty power amplifier, and the second-stage amplification circuit is configured as the second-stage amplification circuit of the carrier amplifier, wherein, the first-stage amplification circuit of the carrier amplifier is configured to receive a part of the RF input signal divided by the power divider, and the second-stage amplification circuit of the carrier amplifier is configured to be connected to the input terminal of a ¼ transmission line and connected to the high power mode input terminal of the power switch through the ¼ transmission line.

In accordance with another aspect of the disclosure, a RF power amplifier based on transformer matching is provided, wherein the Doherty power amplifier further includes a peak amplifier, the first-stage amplification circuit of the peak amplifier is configured to receive another part of the RF input signal divided by the power divider through a phase shifter, and the second-stage amplification circuit of the peak amplifier is configured to be connected to the output terminal of the ¼ transmission line through an secondary power amplifier matching network.

In accordance with another aspect of the disclosure, a RF power amplifier based on transformer matching is provided, wherein the first-stage amplification circuit of the carrier amplifier is connected to the second-stage amplification circuit of the carrier amplifier through a first inter-stage matching network, and wherein the first-stage amplification circuit of the peak amplifier is connected to the second-stage amplification circuit of the peak amplifier through a second inter-stage matching network.

In accordance with another aspect of the disclosure, a RF power amplifier based on transformer matching is provided, wherein the output terminal of the second-stage amplification circuit of the carrier amplifier is configured to be connected to the power supply voltage through a first output-stage choke, and wherein the output terminal of the first-stage amplification circuit of the peak amplifier is configured to be connected to the power supply voltage through an input-stage choke, and the output terminal of the second-stage amplification circuit of the peak amplifier is configured to be connected to the power supply voltage through a second output-stage choke.

In accordance with another aspect of the disclosure, a RF power amplifier based on transformer matching is provided, wherein the turn ratio of the first transformer is determined according to the load impedance of the first-stage amplification circuit.

### BRIEF DESCRIPTION OF THE DRAWINGS

The above and other aspects, features and advantages of certain exemplary embodiments of the present disclosure will be more apparent from the following detailed description in conjunction with the accompanying drawings, in which:

FIG. 1 is a schematic diagram showing the power probability density function of the mobile phone power amplifier of the 3rd generation WCDMA wireless communication system;

FIG. 2 is a schematic diagram showing the power probability density function of the mobile phone power amplifier in 4G LTE and 5G NR wireless communication systems;

FIG. 3 is a schematic diagram showing a two-stage power amplifier with a direct connection output in a medium power mode;

FIG. 4 is a schematic diagram showing a single-ended power amplifier based on a transformer matching high-efficiency medium power structure according to an embodiment of the present disclosure;

FIG. 5 is a schematic diagram showing a push-pull power amplifier based on transformer matching high-efficiency medium power structure according to an embodiment of the present disclosure;

FIG. 6 is a schematic diagram showing a Doherty power amplifier based on a transformer matching high-efficiency medium power structure according to an embodiment of the present disclosure;

FIG. 7 is a diagram showing a linearity index (gain vs output power) of a medium power mode according to an embodiment of the present disclosure;

FIG. 8 is a diagram showing a third-order cross modulation index of a medium power mode according to an embodiment of the present disclosure;

FIG. 9 is a diagram showing a fifth-order cross modulation index of a medium power mode according to an embodiment of the present disclosure; and

FIG. 10 is a diagram showing power additional efficiency according to an embodiment of the present disclosure.

### DETAILED DESCRIPTION OF EXEMPLARY EMBODIMENTS

Before proceeding to the following detailed description, it may be beneficial to set forth the definitions of certain words and phrases used throughout this patent document. The terms “coupled”, “connected” and its derivatives refer to any direct or indirect communication between two or more elements, whether those elements are in physical contact with each other or not. The terms “transmission”, “reception” and “communication” and their derivatives cover direct and indirect communication. The terms “including” and “containing” and their derivatives refer to including but not limited to. The term “or” is inclusive, meaning and/or. The phrase “associated with” and its derivatives refer to including, included in, interconnected with, contained in, connected with, coupled with, communicated with, cooperated with, interwoven with, approached with, bound with, or having the property of. The term “controller” refers to any device, system or part thereof that controls at least one operation. Such a controller may be implemented in hardware or a combination of hardware and software and/or firmware. The functions associated with any particular controller can be centralized or distributed, whether local or remote. The phrase “at least one”, when used with a list of items, means that different combinations of one or more of the listed items can be used, and only one item in the list may be needed. For example, “at least one of A, B and C” includes any one of the following combinations: A, B, C, A and B, A and C, B and C, A and B and C.

Definitions of other specific words and phrases are provided throughout this patent document. It should be understood by those skilled in the art that in many cases, if not most cases, this definition also applies to the previous and future uses of words and phrases so defined.

In this patent document, the application combination of circuit blocks and the division of sub-circuit blocks are only for illustration, and the application combination of circuit blocks and the division of sub-circuit blocks can have different ways within the scope of this disclosure.

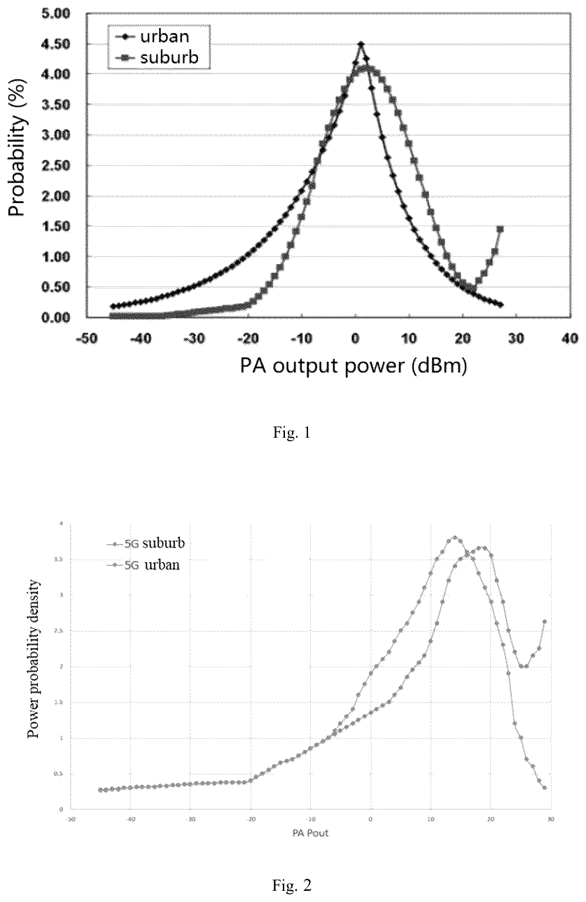

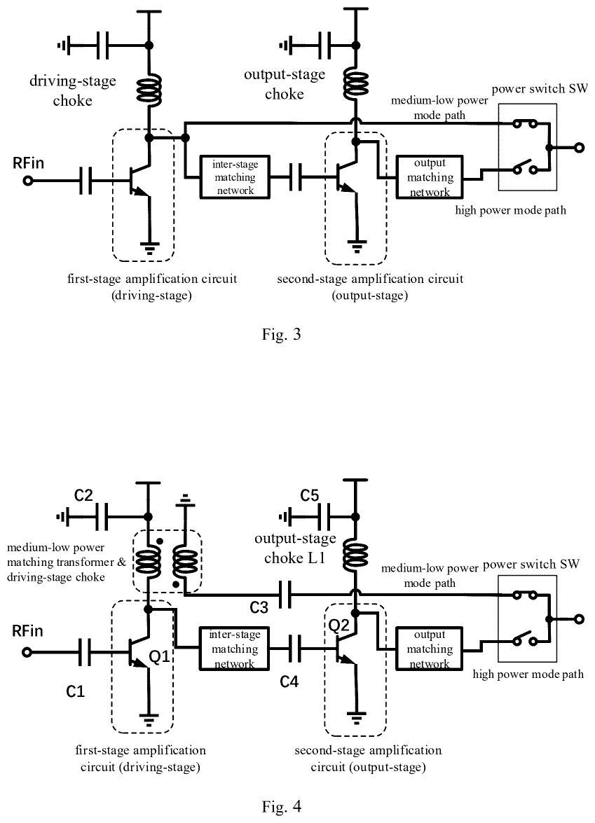

FIGS. 1 to 10 and the embodiments discussed below are for illustration only and should not be interpreted as limiting the scope of the present disclosure in any way. Those skilled in the art will understand that the principles of the present disclosure can be implemented in any suitably arranged system or device.

FIG. 4 is a schematic diagram showing a single-ended power amplifier based on transformer matching high-efficiency medium power structure according to an embodiment of the present disclosure.

Referring to FIG. 4, the single-ended power amplifier includes two-stage amplification circuits, in which the first-stage amplification circuit (driving stage amplification circuit) is configured to be connected to the RF input signal (RFin) through a DC blocking capacitor C1, the power supply terminal of the first-stage amplification circuit is connected to the power supply voltage through a transformer main coil, and its output terminal is connected to the input terminal of the second stage amplification circuit through an inter-stage matching network. The main coil of the transformer is connected between the power supply voltage and the power supply terminal of the first stage amplification circuit, and one terminal of its secondary coil is grounded and the other terminal is connected to the medium-low power mode input terminal of the power switch SW through the capacitor C3. The second stage amplification circuit (output-stage amplification circuit) is configured to receive the amplified signal output by the first-stage amplification circuit through a capacitor C4, its power supply terminal is connected to the power supply voltage through an output-stage choke L1, and its output terminal is connected to the high power mode input terminal of the power switch SW through an output matching network. The power switch is configured as a single-pole double-throw switch or a single-pole multi-throw switch. The power amplifier may further include a capacitor C2 which is configured between the ground node and the power supply terminal of the main coil and a capacitor C5 which is configured between the ground node and one terminal of the output-stage choke L1.

When the first-stage amplification circuit and the second-stage amplification circuit are configured as single-ended amplifiers, the first-stage amplification circuit is configured to include a transistor Q1. The gate of the transistor Q1 is connected to one terminal of the DC blocking capacitor C1 to receive a radio frequency (RF) input signal, the drain of the transistor Q1 is connected to the main coil of a transformer as a power supply terminal, to be connected to a power supply voltage through the main coil of the transformer, and the drain of the transistor Q1 is also connected to an inter-stage matching network to output an amplified signal to the second-stage amplification circuit, and the source of the transistor Q1 is configured to be grounded. The second-stage amplification circuit is configured to include a transistor Q2. The gate of the transistor Q2 is connected to one terminal of a capacitor C4 to receive a radio frequency signal from the first-stage amplification circuit, the drain of the transistor Q2 is connected to the output stage choke L1 as a power supply terminal, to be connected to the power supply voltage through the output stage choke L1, and the drain of the transistor Q2 is also connected to an output matching network to be connected to the high power mode input terminal of the power switch SW, and the source of the transistor Q2 is configured to be grounded.

When the single-ended power amplifier is configured to work in the medium power mode (or the medium-low power mode), the power switch SW is connected with the input terminal of the medium-low power mode path, so that the single-ended power amplifier performs signal amplification through the first-stage amplification circuit, and since the output terminal of the first-stage amplification circuit is connected to the power supply voltage through the main coil (primary coil) of the transformer, the 50 ohm load impedance can be optimized to the optimum load impedance of the first-stage amplification circuit through the transformer to match the medium power mode, so that a high efficiency medium power mode could be established. The turn ratio of this transformer is determined by the following Formula 2.

$${n}^{2} = \frac{50 ohms}{{R}_{Q 1 \_medium \_power}} \qquad Formula 2$$

Wherein RQ1_medium_power is the load impedance of the transistor Q1 in the medium power mode (medium-low power mode), that is, the load impedance of the first-stage amplifier circuit.

When the single-ended power amplifier is configured to work in the high power mode, the single-pole double-throw or single-pole multi-throw power switch is connected to the high power mode input terminal. In this way, the high power mode path is ON, and the medium-low power mode input terminal of the single-pole double-throw or single-pole multi-throw power switch is OFF, which presents a high-impedance state to the transformer of the first-stage amplification circuit. According to the embodiment, the inter-stage matching in the high power mode will not be changed, and the RF performance of the high power mode will not be affected.

FIG. 5 is a schematic diagram showing a push-pull power amplifier based on transformer matching high-efficiency medium-power structure according to an embodiment of the present disclosure.

Referring to FIG. 5, the push-pull power amplifier according to the embodiment of the present disclosure includes two stage amplification circuits, wherein the first-stage amplification circuit (driver-stage amplification circuit) is configured to be connected to a radio frequency input signal (RFin) through a DC blocking capacitor C1. The first-stage amplification circuit is configured to receive a radio frequency input signal, its power terminal is connected to a power supply voltage through a main coil of a transformer T1, and its output terminal is connected to the input terminal of the second-stage amplification circuit through an input coupling transformer T2. The main coil of the transformer T1 is connected between the power supply voltage and the power supply terminal of the first-stage amplification circuit, and one terminal of the secondary coil of the transformer T1 is grounded and the other terminal is connected to the medium-low power mode input terminal of the power switch SW through the capacitor C2. The second-stage amplification circuit (output-stage amplification circuit) includes two amplification branches (a first amplification branch and a second amplification branch), wherein the input terminals of the first amplification branch and the second amplification branch are respectively connected to terminals of the secondary coil of the input coupling transformer T2, and the secondary coil of the input coupling transformer T2 is configured to be grounded at its middle portion. The output terminals of the first amplification branch and the second amplification branch are respectively connected to terminals of the main coil of the output coupling transformer T3, and the main coil of the output coupling transformer T3 is configured to be grounded at its middle portion. The secondary coil of transformer T3 is configured to be grounded at its one terminal, and its other terminal is connected to the high power mode input terminal of the power switch SW. The power switch SW is configured as a single-pole double-throw switch or a single-pole multi-throw switch. The power amplifier may further include a capacitor C5, which is configured between the ground node and the power supply voltage.

When the power amplifier is configured as a push-pull power amplifier, the first-stage amplification circuit is configured to include a transistor Q1, the gate of which is connected to one terminal of the DC blocking capacitor C1 to receive a radio frequency input signal (RFin). The drain of the transistor Q1 is connected to the main coil of the transformer T1 as a power supply terminal to be connected to a power supply voltage through the main coil of the transformer T1, and the drain of the transistor Q1 is also connected to the main coil of the input coupling transformer T2 to provide the radio frequency signal to the second-stage amplification circuit. The source of the transistor Q1 is configured to be grounded. The second-stage amplification circuit is configured to include a transistor Q2 and a transistor Q3. The gate of transistor Q2 is connected to one terminal of capacitor C3 to receive a radio frequency signal from one terminal of the secondary coil of input coupling transformer T2, the drain of transistor Q2 is connected to one terminal of the main coil of output coupling transformer T3 to be connected to the high power mode input terminal of power switch SW through output coupling transformer T3. The source of transistor Q2 is configured to be grounded. The gate of the transistor Q3 is connected to one terminal of the capacitor C4 to receive a radio frequency signal from the other terminal of the secondary coil of the input coupling transformer T2, and the drain of the transistor Q3 is connected to the other terminal of the main coil of the output coupling transformer T3 to be connected to the high power mode input terminal of the power switch SW through the output coupling transformer T3. In addition, the source of the transistor Q3 is configured to be grounded.

When the power amplifier is configured to work in a medium power mode (or a medium-low power mode), the power switch SW is connected to the medium-low power mode input terminal, so that the power amplifier performs signal amplification through the first-stage amplification circuit, and since the output terminal of the first-stage amplification circuit is connected to the power supply voltage through the main coil (primary coil) of the transformer, the 50 ohm load impedance can be optimized to the optimum load impedance of the first-stage amplification circuit through the transformer to match the medium-power output mode, so as to realize a high-efficiency medium-power mode (medium-low power mode) amplification.

When the power amplifier is configured to work in the high power mode, the single-pole double-throw or single-pole multi-throw power switch is connected to the high power mode input terminal, in this way, the high power mode path is ON, and the medium-low power mode input terminal of the single-pole double-throw or multi-throw power switch is OFF, which presents a high-impedance state to the transformer of the first-stage amplification circuit. According to the embodiment, the inter-stage matching in the high power mode will not be changed, and the RF performance of the high power mode will not be affected.

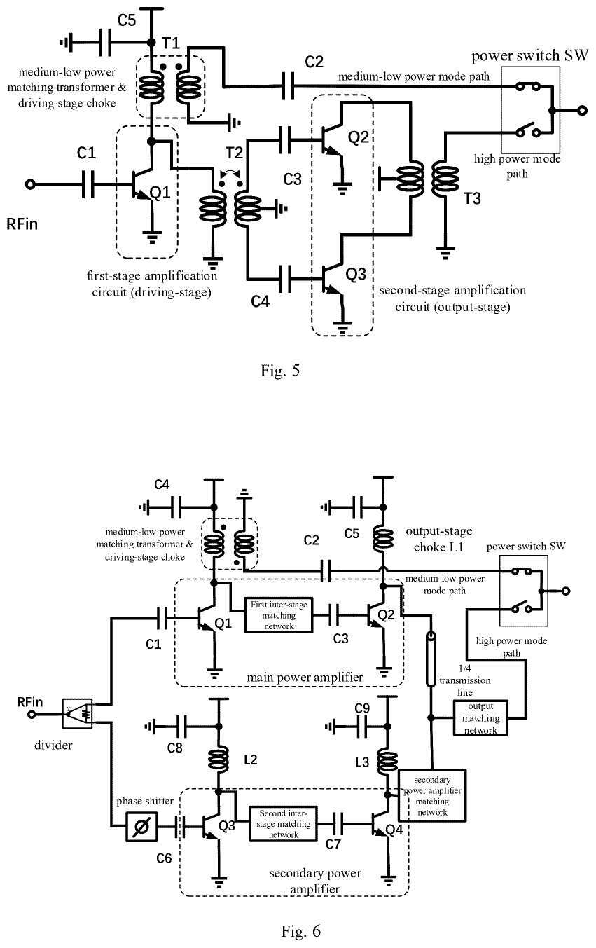

FIG. 6 is a schematic diagram showing a Doherty power amplifier based on a transformer matching high-efficiency medium-power structure (or medium-low power mode) according to an embodiment of the present disclosure.

Referring to FIG. 6, a Doherty power amplifier according to an embodiment of the present disclosure includes a main power amplifier circuit (carrier amplifier) and a secondary power amplifier circuit (peak amplifier), wherein the carrier amplifier and the peak amplifier are configured as two-stage amplification circuits.

The first-stage amplification circuit (driver-stage amplification circuit) in the carrier amplifier is configured to be connected to one terminal of the DC blocking capacitor C1 to receive a part of a radio frequency input signal (RFin) divided by the power divider, the power supply terminal of the first-stage amplification circuit is connected to the power supply voltage through the main coil of the transformer, and its output terminal is connected to the input terminal of the second-stage amplification circuit through the first inter-stage matching network. The main coil of the transformer is connected between the power supply voltage and the power supply terminal of the first-stage amplification circuit of the carrier amplifier, and one terminal of its secondary coil is grounded and the other terminal is connected to the medium-low power mode input terminal of the power switch SW through the capacitor C2. The second-stage amplification circuit (output-stage amplification circuit) of the carrier amplifier is configured to receive the amplified signal output by the first-stage amplification circuit through the capacitor C3, its power supply terminal is connected to the power supply voltage through the output-stage choke L1, and its output terminal is connected to the input terminal of the ¼ transmission line, to be connected to the output terminal of the peak amplifier through the ¼ transmission line. The output terminal of the output matching network is configured to be connected to the high power mode input terminal of the power switch SW. The power switch SW is configured as a single-pole double-throw switch or a single-pole multi-throw switch. The carrier amplifier may further include a capacitor C2 which is configured between the ground node and the power supply terminal of the main coil and a capacitor C5 which is configured between the ground node and one terminal of the output-stage choke L1.

The first-stage amplification circuit (driving-stage amplification circuit) in the peak amplifier is configured to be connected to one terminal of the DC blocking capacitor C6 to receive another part of the RF input signal (RFin) divided by the power divider through the phase shifter and the capacitor C6. The power supply terminal of the first-stage amplification circuit of the peak amplifier is connected to the power supply voltage through the input-stage choke L2, and its output terminal is connected to the input terminal of the second-stage amplification circuit through the second inter-stage matching network. The second-stage amplification circuit (output-stage amplification circuit) of the peak amplifier is configured to receive the amplified signal output by the first-stage amplification circuit through the capacitor C7, its power supply terminal is connected to the power supply voltage through the output-stage choke L3, and its output terminal is connected to the output terminal of the carrier amplifier (the output terminal of the ¼ transmission line) through the secondary power amplifier matching network and is further connected to the input terminal of the output matching network. The peak amplifier may further include a capacitor C8 which is configured between the ground node and one terminal of the input-stage choke L2 and a capacitor C9 which is configured between the ground node and one terminal of the output-stage choke L3.

When the power amplifier is configured as a Doherty power amplifier, the first-stage amplification circuit of the carrier amplifier is configured to include a transistor Q1, the gate of which is connected to one terminal of the DC blocking capacitor C1 to receive the RF input signal. The drain of the transistor Q1 is connected to the main coil of the transformer (medium-low power matching transformer) as a power terminal to be connected to the power supply voltage through the main coil of the transformer, and the drain of the transistor Q1 is also connected to the first inter-stage matching network to output the amplified signal to the second-stage amplification circuit, and the source of the transistor Q1 is configured to be grounded. The second-stage amplification circuit of the carrier amplifier is configured to include a transistor Q2, the gate of which is connected to one terminal of a capacitor C3 to receive a radio frequency signal from the first-stage amplification circuit of the carrier amplifier. The drain of the transistor Q2 is connected to the output stage choke L1 as a power supply terminal to be connected to the power supply voltage through the output stage choke L1, and the drain of the transistor Q2 is also configured to be connected to the input terminal of a ¼ transmission line, to be connected to the input terminal of an output matching network through the ¼ transmission line, so that it could be connected to the high power mode input terminal of the power switch SW through the output matching network. The source of the transistor Q2 is grounded.

The first-stage amplification circuit of the peak amplifier is configured to include a transistor Q3, the gate of which is connected to one terminal of the DC blocking capacitor C6 to receive the RF input signal (RFin) through the phase shifter. The drain of the transistor Q3 is connected to the input-stage choke L2 as a power supply terminal, to be connected to the power supply voltage through the input-stage choke L2, and the drain of the transistor Q3 is also connected to the second inter-stage matching network to output the amplified signal to the second-stage amplification circuit of the peak amplifier. The source of the transistor Q3 is configured to be grounded. The second-stage amplification circuit of the peak amplifier is configured to include a transistor Q4, the gate of which is connected to one terminal of a capacitor C7 to receive a radio frequency signal from the first-stage amplification circuit of the peak amplifier. The drain of the transistor Q4 is connected to an output-stage choke L3 as a power supply terminal, to be connected to the power supply voltage through the output-stage choke L3, and the drain of the transistor Q4 is also configured to be connected to an input terminal of an output matching network through an secondary power amplifier matching network, to be connected to a high power mode input terminal of the power switch SW through the output matching network. The source of the transistor Q4 is grounded.

When the power amplifier is configured to work in a medium-power mode (or a medium-low power mode), the power switch SW is connected to the medium-low power mode input terminal, so that the power amplifier performs signal amplification through the first-stage amplification circuit of the carrier amplifier, and since the output terminal of the first-stage amplification circuit is connected to the power supply voltage through the main coil (primary coil) of the transformer, the 50 ohm load impedance can be optimized to the optimum load impedance of the first-stage amplification circuit through the transformer to match the medium-power output mode, so as to realize a high-efficiency medium-power mode (medium-low power mode) amplification.

When the power amplifier is configured to work in the high power mode, the single-pole double-throw or single-pole multi-throw power switch is connected to the high power mode input terminal, in this way, the high power mode path is ON, and the medium-low power mode input terminal of the single-pole double-throw or multi-throw power switch is OFF, which presents a high-impedance state to the medium-low power matching transformer of the first-stage amplification circuit. According to the embodiment, the inter-stage matching in the high power mode will not be changed, and the RF performance of the high power mode will not be affected.

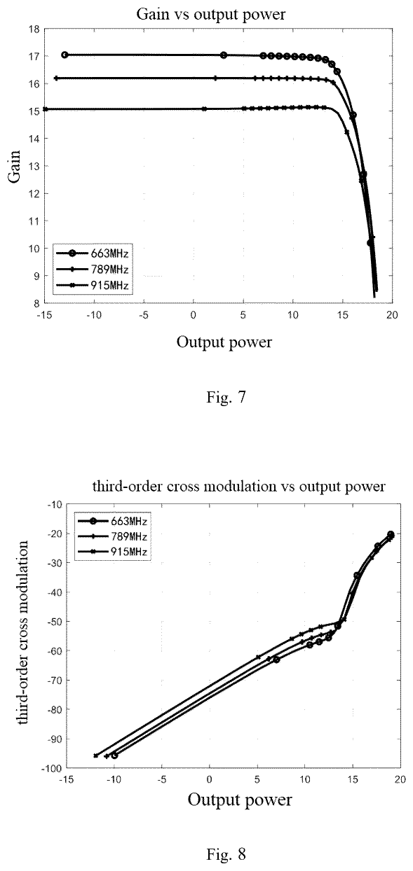

FIG. 7 is a diagram showing a linearity index (gain vs output power) of a medium-power operation mode according to an embodiment of the present disclosure. Referring to FIG. 7, the power amplifier based on transformer matching according to the embodiment of the present disclosure has good linearity in the medium-power working mode, wherein the saturated power of the power working mode is about 18 dBm, which is 4 dB higher than the rated power, thus ensuring the linearity of the rated power in the state without DPD.

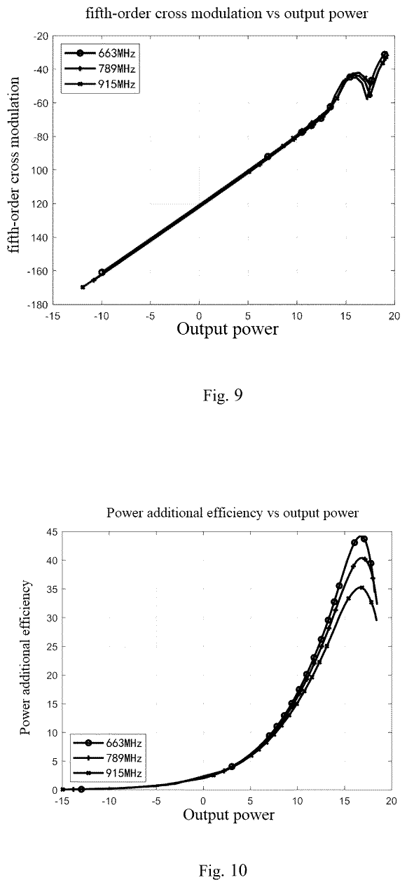

FIG. 8 is a diagram showing a third-order cross modulation index of a medium power mode according to an embodiment of the present disclosure, and FIG. 9 is a diagram showing a fifth-order cross modulation index of a medium power mode according to an embodiment of the present disclosure. Referring to FIG. 8, when the power amplifier according to the embodiment of the present disclosure works in the medium power mode, its third-order cross modulation value is less than −50 dBc when the output power is less than 14 dBm. Referring to FIG. 9, when the power amplifier according to the embodiment of the present disclosure works in the medium power mode, its fifth-order cross modulation value is less than −60 dBc when the output power is less than 14 dBm.

FIG. 10 is a diagram showing power additional efficiency according to an embodiment of the present disclosure. Referring to FIG. 10, when the first-stage power supply voltage is 1.7 volts and the output power is 14 dBm, the medium power output efficiency of the power amplifier based on transformer matching is between 30% and 34%, which is 10% to 15% more efficient than the medium power mode of the traditional scheme directly connecting the first-stage amplifier circuit and the output terminal. And it has no significant effect on the high power operation mode.

In FIG. 7 to FIG. 10, the power amplifier is configured to operate at 663 MHz, 789 MHz and 915 MHz, which belongs to the Low Band region where the 4G/5G frequency band is below 1 GHz, but those skilled in the art should understand that the above examples are only for illustration, and the power amplifier according to the embodiment of the present disclosure can operate in other operating frequency bands of 4G LTE and 5G NR.

Although the present disclosure has been described with exemplary embodiments, various changes and modifications can be suggested to those skilled in the art. This disclosure is intended to cover such changes and modifications as fall within the scope of the appended claims.

Any description in the present disclosure should not be understood as implying that any particular element, step or function is an essential element that must be included within the scope of the claims. The scope of the patent subject matter is limited only by the claims.

What is claimed is:

1. A radio frequency power amplifier based on transformer matching, including:
a first-stage amplification circuit configured with an input terminal for receiving a radio frequency input signal and an output terminal connected to an input terminal of a second-stage amplification circuit, wherein the output terminal of the first-stage amplification circuit is also configured to be connected to one terminal of a main coil of a first transformer, to be connected to a power supply voltage through the main coil of the first transformer;
the first transformer configured to include the main coil and a secondary coil, wherein the main coil is configured between the power supply voltage and the output terminal of the first-stage amplification circuit, and one terminal of the secondary coil is grounded and the other terminal of the secondary coil is connected to a medium-low power mode input terminal of a power switch through a first capacitor;
the second-stage amplification circuit configured with the input terminal for receiving the amplified radio frequency signal from the first-stage amplification circuit, and its output terminal configured to be connected to a high power mode input terminal of the power switch; and
the power switch configured as a single-pole double-throw switch or a single-pole multi-throw switch, wherein the power switch is configured to be connected with the medium-low power mode input terminal when the radio frequency power amplifier works in the medium-low power mode, and to be connected with the high power mode input terminal when the radio frequency power amplifier works in the high power mode.

2. The radio frequency power amplifier of claim 1, wherein the first-stage amplification circuit and the second-stage amplification circuit are configured as single-ended power amplifiers,
wherein the output terminal of the first-stage amplification circuit is connected to the input terminal of the second-stage amplification circuit through an inter-stage matching network, and
wherein the output terminal of the second-stage amplification circuit is connected to the high power mode input terminal of the power switch through an output matching network.

3. The radio frequency power amplifier of claim 2, wherein the output terminal of the second-stage amplification circuit is further configured to be connected to the power supply voltage through an output stage choke.

4. The radio frequency power amplifier of claim 1, wherein the second-stage amplification circuit is configured as a push-pull power amplifier, which includes an input coupling transformer, a first amplification branch, a second amplification branch and an output coupling transformer,
wherein the output terminal of the first-stage amplification circuit is connected to one terminal of a main coil of the input coupling transformer, and the other terminal of the main coil of the input coupling transformer is grounded,
wherein the input terminal of the first amplification branch and the input terminal of the second amplification branch are respectively connected to one of two terminals of a secondary coil of the input coupling transformer, and the output terminal of the first amplification branch and the output terminal of the second amplification branch are respectively connected to one of two terminals of the main coil of the output coupling transformer,
wherein one terminal of the secondary coil of the output coupling transformer is configured to be grounded, and the other terminal is connected to the high power mode input terminal of the power switch.

5. The radio frequency power amplifier of claim 4, wherein the secondary coil of the input coupling transformer is configured to be grounded at the middle portion, and the main coil of the output coupling transformer is configured to be grounded at the middle portion.

6. The radio frequency power amplifier of claim 1, wherein the radio frequency power amplifier is configured as a Doherty power amplifier, the first-stage amplification circuit is configured as a first-stage amplification circuit of a carrier amplifier in the Doherty power amplifier, and the second-stage amplification circuit is configured as a second-stage amplification circuit of the carrier amplifier,
wherein the first-stage amplification circuit of the carrier amplifier is configured to receive a part of the radio frequency input signal divided by a power divider, and the second-stage amplification circuit of the carrier amplifier is configured to be connected to the input terminal of a ¼ transmission line and connected to the high power mode input terminal of the power switch through the ¼ transmission line.

7. The radio frequency power amplifier of claim 6, wherein the Doherty power amplifier further includes a peak amplifier, a first-stage amplification circuit of the peak amplifier is configured to receive another part of the radio frequency input signal divided by the power divider through a phase shifter, and
a second-stage amplification circuit of the peak amplifier is configured to be connected to the output terminal of the ¼ transmission line through a secondary power amplifier matching network.

8. The radio frequency power amplifier of claim 7, wherein the first-stage amplification circuit of the carrier amplifier is connected to the second-stage amplification circuit of the carrier amplifier through a first inter-stage matching network, and
wherein the first-stage amplification circuit of the peak amplifier is connected to the second-stage amplification circuit of the peak amplifier through a second inter-stage matching network.

9. The radio frequency power amplifier of claim 7, wherein the output terminal of the second-stage amplification circuit of the carrier amplifier is configured to be connected to the power supply voltage through a first output-stage choke, and
wherein the output terminal of the first-stage amplification circuit of the peak amplifier is configured to be connected to the power supply voltage through an input-stage choke, and the output terminal of the second-stage amplification circuit of the peak amplifier is configured to be connected to the power supply voltage through a second output-stage choke.

10. The radio frequency power amplifier of claim 1, wherein the turn ratio of the first transformer is determined according to the load impedance of the first-stage amplification circuit.
